(19) United States
(12) Patent Application Publication
(10) Pub. No.: US 2026/0020311 A1
(43) Pub. Date: Jan. 15, 2026

(54) SEMICONDUCTOR DEVICE AND METHOD OF MANUFACTURING THE SAME

(71) Applicants: Kabushiki Kaisha Toshiba, Tokyo (JP); Toshiba Electronic Devices & Storage Corporation, Tokyo (JP)

(72) Inventor: Tatsuya OHGURO, Kanazawa (JP)

(73) Assignees: Kabushiki Kaisha Toshiba, Tokyo (JP); Toshiba Electronic Devices & Storage Corporation, Tokyo (JP)

(21) Appl. No.: 19/006,487

(22) Filed: Dec. 31, 2024

(30) Foreign Application Priority Data
Jul. 10, 2024 (JP) 2024-110937

(51) Int. Cl. H10D 64/23; H01L 21/288; H01L 23/00; H01L 23/373; H10D 30/66; H10D 64/01; H10D 64/64

(52) U.S. Cl. CPC H10D 64/2527; H01L 21/2885; H01L 23/3735; H01L 24/32; H10D 30/668; H10D 64/01; H10D 64/647; H01L 2224/32112; H01L 2224/32221

(57) ABSTRACT

A semiconductor device includes a substrate, a first electrode and a second electrode. The semiconductor device includes a MOSFET that has the first electrode as a drain electrode and the second electrode as a source electrode. The first electrode has a layer region provided on a first main surface and a first region extending from the first main surface into the substrate in a first direction from the first electrode to the second electrode. A lower surface of the first electrode protrudes in a direction opposite to the first direction.

### CROSS-REFERENCE TO RELATED APPLICATIONS

This application is based upon and claims the benefit of priority from Japanese Patent Application No. 2024-110937 filed on Jul. 10, 2024, and the entire contents of which are incorporated herein by reference.

### FIELD

Embodiments described herein relate generally to a semiconductor device and a method of manufacturing the same.

### BACKGROUND

Resistances of a vertical metal oxide semiconductor field effect transistor (MOSFET) used in a semiconductor device include a substrate resistance and a resistance of a drain electrode. The drain electrode is also one of heat dissipation paths of the semiconductor device.

### BRIEF DESCRIPTION OF THE DRAWINGS

FIG. 1 is a cross-sectional view illustrating a semiconductor device according to a first embodiment.

FIG. 2 is a cross-sectional view illustrating a semiconductor device according to the first embodiment.

FIG. 3 is a cross-sectional view illustrating a semiconductor device according to a second embodiment.

FIG. 4 is a cross-sectional view illustrating a semiconductor device according to the second embodiment.

FIG. 5 is a cross-sectional view illustrating a semiconductor device according to a third embodiment.

FIG. 6 is a top view illustrating a semiconductor device according to a fourth embodiment.

FIG. 7 is a top view illustrating a semiconductor device according to the fourth embodiment.

FIG. 8 is a top view illustrating a semiconductor device according to the fourth embodiment.

FIG. 9 is a cross-sectional view taken along an XY plane illustrating a semiconductor device according to a fifth embodiment.

FIG. 10 is a cross-sectional view taken along an XY plane illustrating a semiconductor device according to a first modification of the fifth embodiment.

FIG. 11 is a cross-sectional view taken along an XY plane illustrating a semiconductor device according to a second modification of the fifth embodiment.

FIG. 12 is a cross-sectional view illustrating the semiconductor device according to the second modification of the fifth embodiment.

FIG. 13 is a cross-sectional view taken along an XY plane illustrating a semiconductor device according to a sixth embodiment.

FIG. 14A is a cross-sectional view illustrating a step of providing a resist on a first main surface of a substrate.

FIG. 14B is a cross-sectional view illustrating a step of selectively excavating the first main surface of the substrate.

FIG. 14C is a cross-sectional view illustrating a step of forming a first metal layer in an opening.

FIG. 14D is a cross-sectional view illustrating a step of forming a first electrode.

FIG. 14E is a cross-sectional view illustrating a step of forming a second metal layer.

FIG. 14F is a cross-sectional view illustrating a step of providing a chip on a conductor.

FIG. 14G is a cross-sectional view illustrating a step of forming a bonding layer.

### DETAILED DESCRIPTION

Hereinafter, embodiments of the present invention will be described with reference to the drawings.

According to one embodiment, a semiconductor device includes a substrate having a first main surface and a second main surface on a side opposite to the first main surface, a first electrode provided on the first main surface, a second electrode provided on the second main surface, and a MOSFET provided on the second main surface side of the substrate and having the first electrode as a drain electrode and the second electrode as a source electrode, wherein the first electrode has a layer region provided on the first main surface, and a first region extending from the first main surface into the substrate in a first direction from the first electrode toward the second electrode, the first region being adjacent to the layer region, and a lower surface of the first electrode protrudes in a direction opposite to the first direction in the first region.

Note that the drawings are schematic or conceptual, and the relationship between the thickness and the width of each portion, the ratio of the sizes between the portions, and the like are not necessarily the same as actual ones.

In addition, even in the case of representing the same portion, dimensions and ratios may be represented differently from each other depending on the drawings.

For example, in the cross-sectional views illustrated in the present specification, a laminated structure is illustrated, but the ratio of the thicknesses of each layer of the laminated structure is not necessarily the same as an actual one.

Even in a case where one layer is illustrated to be thicker than another layer in the cross-sectional view, there may be a case where the thicknesses of the one layer and the other layer are substantially the same or a case where the one layer is thinner than the other layer in reality.

That is, dimensions such as thicknesses illustrated in the drawings in the present specification may be different from actual dimensions.

A direction from a first electrode 11 to a second electrode 12 is defined as a Z direction (first direction).

A direction orthogonal to the Z direction is defined as an X direction (second direction), and a direction intersecting the X direction and the Z direction is defined as a Y direction (third direction). Note that the X direction, the Y direction, and the Z direction are illustrated in an orthogonal relationship in the present embodiment, but are not limited to the orthogonal relationship, and may be any relationship in which the X direction, the Y direction, and the Z direction intersect each other.

For the sake of description, the positive direction of the Z direction will be referred to as an “up direction”, and the negative direction of the Z direction will be referred to as a “down direction”. However, the “up” and “down” directions are not limited to a gravity direction or a direction at the time of mounting a semiconductor device. The term “thickness” indicates a length in the Z direction.

A state in which members face each other via a first metal layer ML1 or a second metal layer ML2 may be described as a state in which the members are in contact with each other via the first metal layer ML1 or the second metal layer ML2, or a state in which the members are simply in contact with each other, or a state in which the members are in contact with each other.

In the following description, notations n⁺, n, and n⁻ and p⁺, p, and p⁻ represent relative levels of impurity concentration in each conductivity type. That is, n⁺ indicates that the n-type impurity concentration is relatively higher than that of n, and n⁻ indicates that the n-type impurity concentration is relatively lower than that of n. In addition, p⁺ indicates that the p-type impurity concentration is relatively higher than that of p, and p⁻ indicates that the p-type impurity concentration is relatively lower than that of p. Note that n⁺ type and n⁻ type may be simply referred to as n type, p⁺ type, and p⁻ type may be simply referred to as p type.

Note that, in the present specification and each drawing, the same elements as those described above with respect to the previously described drawings are denoted by the same reference numerals, and detailed description thereof will be omitted as appropriate.

### First Embodiment

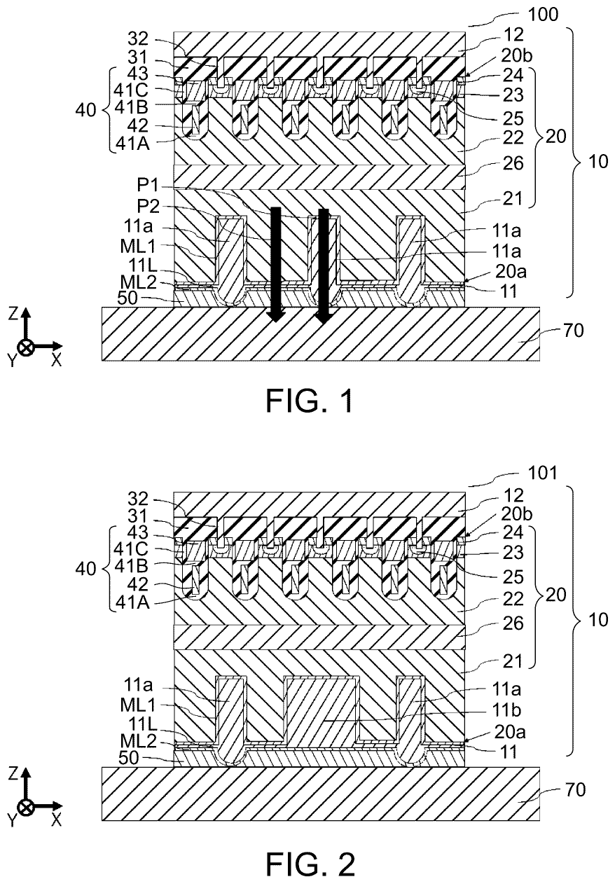

FIG. 1 is a cross-sectional view illustrating a semiconductor device 100 according to a first embodiment.

The semiconductor device 100 illustrated in FIG. 1 is, for example, a MOSFET. The semiconductor device 100 includes a chip 10 having a first electrode 11, a substrate 20, a control region 40, an insulating layer 31, a second electrode 12 and a plug 32, and includes a bonding layer 50 and a conductor 70. The first electrode 11 is, for example, a drain electrode of a MOSFET. The second electrode 12 is, for example, a source electrode of a MOSFET.

The substrate 20 has a first main surface 20a (lower surface) intersecting the Z direction and a second main surface 20b (upper surface) located on a side opposite to the first main surface 20a. The first electrode 11 extends in the positive direction of the Z direction in the substrate 20 from the first main surface 20a. A first region 11a of the first electrode 11 extends in the Z direction in the substrate 20. A layer region 11L of the first electrode 11 is provided along the first main surface 20a of the substrate 20. A first metal layer ML1 is interposed between the first electrode 11 and the substrate 20. The first electrode 11 is in contact with the bonding layer 50 via a second metal layer ML2 on the lower surface. The control region 40 extends in the negative direction of the Z direction in the substrate 20 from the second main surface 20b.

The substrate 20 includes a first semiconductor region 21 of a first conductivity type (n⁺-type drain region), a second semiconductor region 22 (n⁻-type drift region), a third semiconductor region 23 of a second conductivity type (p-type base region), a fourth semiconductor region 24 of the first conductivity type (n⁺-type source region), a fifth semiconductor region 25 of the second conductivity type (p⁺-type contact region), and a sixth semiconductor region 26 of the first conductivity type (n⁺-type buffer region).

The first semiconductor region 21 is provided on the first electrode 11 at a position closest to the first main surface 20a. The second semiconductor region 22 is provided on the first semiconductor region 21. It is desirable to provide the sixth semiconductor region 26 between the first semiconductor region 21 and the second semiconductor region 22. The third semiconductor region 23 is provided on the second semiconductor region 22. The fourth semiconductor region 24 is provided on the third semiconductor region 23.

The sixth semiconductor region 26 has an impurity concentration of the first conductivity type higher than that of the second semiconductor region 22. The sixth semiconductor region 26 may have an impurity concentration of the first conductivity type higher than that of the first semiconductor region 21. The sixth semiconductor region 26 may have the same impurity concentration of the first conductivity type as the first semiconductor region 21. In this case, the sixth semiconductor region 26 may be regarded as part of the first semiconductor region 21, and it can be said that the first semiconductor region 21 is in contact with the second semiconductor region 22.

The control region 40 includes a first insulating film 41A in contact with the substrate 20, a conductive region 42 provided in the first insulating film 41A and facing the substrate 20 via the first insulating film 41A, and a gate electrode 43 provided above the conductive region 42 via a second insulating film 41B and facing the third semiconductor region 23 via a gate insulating film 41C. The conductive region 42 is a field plate connected to the second electrode 12 via, for example, a structure not illustrated in FIG. 1. A plurality of control regions 40 are provided, and are arranged side by side in the X direction and extend in the Y direction as illustrated in FIG. 1, for example. On the other hand, the control regions 40 may be provided in a grid pattern on the XY plane.

The insulating layer 31 is provided to cover the control region 40. The second electrode 12 is provided on the insulating layer 31. The plug 32 extending in the insulating layer 31 and the fourth semiconductor region 24 of the first conductivity type and electrically connected to the third semiconductor region 23 of the second conductivity type is electrically connected to the second electrode 12. The plug 32 is connected to the third semiconductor region 23 via the fifth semiconductor region 25.

The chip 10 is connected to the conductor 70 via the bonding layer 50. The conductor 70 and the first electrode 11 face each other via the bonding layer 50. The second metal layer ML2 may be interposed between the first electrode 11 and the bonding layer 50. The conductor 70 is, for example, a die pad.

Although not illustrated in FIG. 1, the third electrode 13 is provided on the insulating layer 31 so as to be separated from the second electrode 12. The third electrode 13 is, for example, a gate pad electrically connected to the gate electrode 43.

In addition, a conductor (not illustrated in FIG. 1) may be provided on the second electrode 12 and the third electrode 13 via a bonding layer (not illustrated in FIG. 1). The conductor is, for example, a metal plate. The third electrode 13 may be provided with a bonding wire instead of the metal plate.

Next, an example of a material of each constituent will be described.

The first electrode 11 is, for example, a metal containing Cu. The second electrode 12 is, for example, a metal containing Cu or Al. The first metal layer ML1 contains, for example, at least one of Ti, Cu, Ta, N, TiCu, TiNCu, TiN, or TaN. The first metal layer ML1 desirably has a structure of at least two layers in which a layer containing Ti and a layer containing Cu are laminated in a direction from the substrate 20 toward the first electrode 11.

The substrate 20 is, for example, a semiconductor containing at least one of C, Si, Ge, SiC, GaN, or AlN. The semiconductor layer of the first conductivity type is formed by injecting, for example, P or As into the substrate 20 and then performing thermal diffusion. The semiconductor layer of the second conductivity type is formed by injecting, for example, B or Ga into the substrate 20 and then performing thermal diffusion.

The first insulating film 41A, the second insulating film 41B, and the gate insulating film 41C are oxide films containing silicon oxide such as SiO₂. The conductive region 42 is, for example, conductive polysilicon containing impurities. The gate electrode 43 is, for example, conductive polysilicon containing impurities.

The insulating layer 31 is, for example, an oxide film containing silicon oxide such as SiO₂. The plug 32 is, for example, a metal containing Al or W.

The bonding layer 50 is, for example, solder. The bonding layer 50 contains, for example, at least one metal element of Sn, Pb, or Ag. The second metal layer ML2 contains, for example, at least one metal element of Ti, Ni, Ag, or Au. It is desirable that the second metal layer ML2 contains Ti and Ni and contains Ag or Au, and further, it is desirable that the second metal layer ML2 has a three-layer structure of Ti, Ni, and Ag in this order from the first electrode 11 toward the bonding layer 50. The conductor 70 contains, for example, Cu.

To summarize the thermal conductivity of each material, the thermal conductivity of the first electrode 11 is higher than the thermal conductivity of the substrate 20. The thermal conductivity of the substrate 20 is higher than the thermal conductivity of the bonding layer 50. The thermal conductivity of the first electrode 11 and the thermal conductivity of the conductor 70 are, for example, approximately the same. Specifically, the thermal conductivity of Cu is approximately 398 W/mK, the thermal conductivity of Si is approximately 160 W/mK, and the thermal conductivity of the solder is approximately 49 W/mK.

Next, structures of the first electrode 11 and the bonding layer 50 will be further described.

The first electrode 11 includes a first region 11a extending in the substrate 20 in a direction from the first main surface 20a toward the second electrode 12, and a layer region 11L provided adjacent to the first region 11a along the first main surface 20a. The first region 11a faces the first semiconductor region 21 in the X direction. The first region 11a is located in the first semiconductor region 21, in the negative direction of the Z direction relative to the sixth semiconductor region 26.

At least a part of the first region 11a is located in the negative direction of the Z direction relative to the layer region 11L. The lower surface of the first electrode 11 protrudes in the negative direction of the Z direction in the first region 11a.

Here, the fact that a surface of a certain region protrudes in the negative direction of the Z direction indicates that a profile of a surface shape in the X direction protrudes in the negative direction of the Z direction, and an absolute value of the step in the Z direction of the protrusion shape from the top of the protrusion shape along the positive direction and the negative direction of the X direction is equal to or more than a predetermined length. Here, the predetermined length is, for example, 1.0 μm. The predetermined length may be 2.0 μm or 3.0 μm. The predetermined length may be 4.0 μm or 5.0 μm.

As will be described later, the fact that a surface of a certain region is recessed in the positive direction of the Z direction indicates that a profile of a surface shape in the X direction is recessed in the positive direction of the Z direction, and an absolute value of the step in the Z direction of the recessed shape from the bottom of the recessed shape in the positive direction and the negative direction of the X direction is equal to or more than a predetermined length. Here, the predetermined length is, for example, 5.0 μm. The predetermined length may be 10.0 μm, 20.0 μm, or 30.0 μm.

In contrast, the flat surface is a structure that does not protrude and is not recessed, that is, does not have a step of a predetermined length or more. Here, the predetermined length is, for example, 1.0 μm. The predetermined length may be 2.0 μm or 3.0 μm. The predetermined length may be 4.0 μm or 5.0 μm.

The lower surface of the first electrode 11 is covered with the second metal layer ML2. The bonding layer 50 is provided between the second metal layer ML2 and the conductor 70. The upper surface of the conductor 70 is, for example, flat. The first electrode 11 and the bonding layer 50 are in contact with each other via the second metal layer ML2.

A thickness of the bonding layer 50 in the Z direction is smaller in a region in contact with the first region 11a than in a region in contact with the layer region 11L. The thickness of the bonding layer 50 in the Z direction may be 0 in the region in contact with the first region 11a. That is, the bonding layer 50 may not exist below the first region 11a, and a part of the lower surface of the first electrode 11 may be in contact with the conductor 70 without being covered with the bonding layer 50 below the first region 11a. The first region 11a and the conductor 70 may be in contact with each other via the second metal layer ML2 with the bonding layer 50 interposed between the first region 11a and the conductor 70, or the first region 11a and the conductor 70 may be in contact with each other via the second metal layer ML2 without the bonding layer 50 interposed between the first region 11a and the conductor 70. From the viewpoint of heat dissipation that will be described later, it is desirable to make the bonding layer 50 below the first region 11a thin.

An operation of the semiconductor device 100 will be described.

First, when a voltage is applied to the gate electrode 43 and exceeds a threshold voltage, a channel is formed in the third semiconductor region 23 facing the gate electrode 43 via the gate insulating film 41C. For example, an n-type channel is formed in the third semiconductor region 23 that is a p-type base region. Thus, the semiconductor device 100 is turned on.

Subsequently, for example, when a positive voltage is applied to the first electrode 11 with reference to the second electrode 12, a current flows from the first electrode 11 toward the second electrode 12. The current flows to the second electrode 12 via the first electrode 11, the first semiconductor region 21, the sixth semiconductor region 26, the second semiconductor region 22, the channel formed in the third semiconductor region 23, the fourth semiconductor region 24, and the plug 32.

Next, when the voltage applied to the gate electrode 43 is made smaller than the threshold voltage, the channel of the third semiconductor region 23 disappears. The semiconductor device 100 is turned off.

When the semiconductor device 100 is turned off, electrons accumulated in the second semiconductor region 22 in the on state are discharged from the first electrode 11, and a depletion layer expands.

The depletion layer expands from the second electrode 12 to the first electrode 11. By controlling the potential of the conductive region 42 to, for example, the same potential as the potential of the first electrode 11 or the second electrode 12, the expansion of the depletion layer is promoted, and the electric field concentration is alleviated.

Further, the sixth semiconductor region 26 has an impurity concentration higher than that of the second semiconductor region 22, so that the expansion of the depletion layer can be reliably stopped in the sixth semiconductor region 26. Punch-through due to contact between the depletion layer and the first electrode 11 is suppressed by the sixth semiconductor region 26, and a stable turn-off operation can be realized.

According to the semiconductor device 100 of the present embodiment, the reliability of the semiconductor device can be improved by improving the heat dissipation from the chip 10 to the conductor 70. At the same time, by increasing the thickness of the bonding layer 50 in the Z direction below the layer region 11L, the bonding strength between the chip 10 and the conductor 70 can be improved. In general, uniformly reducing the thickness of the bonding layer 50 in the Z direction in order to improve heat dissipation may reduce bonding strength. According to the semiconductor device according to the present embodiment, it is possible to improve a trade-off between heat dissipation and bonding strength.

Since the first electrode 11 having a higher thermal conductivity than that of the substrate 20 and the bonding layer 50 serves as a heat flow path, heat generated in the substrate 20 is efficiently released to the conductor 70 through the first electrode 11. The accumulation of heat in the substrate 20 is suppressed, and the reliability of the semiconductor device is improved.

A description will be made while comparing paths P1 and P2 of the heat flow illustrated in FIG. 1. The path P1 reaches the conductor 70 from the substrate 20 through the first region 11a. The thickness in the Z direction of the bonding layer 50 through which the path P1 passes is smaller than that of the path P2. On the other hand, the thickness in the Z direction of the first electrode 11 through which the path P1 passes is larger than that of the path P2. Since the first electrode 11 has a higher thermal conductivity than that of the bonding layer 50 and the substrate 20, the path P1 is more likely to make heat flow than the path P2.

The path P2 passes through a portion of the substrate 20 located between the first regions 11a in the X direction. The substrate 20 has a lower thermal conductivity than that of the first electrode 11, and the path P2 has lower thermal conductance than that of the path P1.

According to the semiconductor device of the present embodiment, it is possible to improve the efficiency of heat dissipation from the chip 10 to the conductor 70 by providing a heat dissipation path passing through the path P1.

On the other hand, since the bonding layer 50 is thick in the Z direction at the portion in contact with the layer region 11L via the second metal layer ML2, the bonding strength between the chip 10 and the conductor 70 can be maintained. In particular, compared with an example in which the heat dissipation is improved by uniformly reducing the thickness of the entire bonding layer 50 in the Z direction, the bonding strength between the chip 10 and the conductor 70 can be increased by maintaining the thickness in the Z direction at a part of the bonding layer 50 in the present embodiment.

By forming the first region 11a such that the lower surface of the first electrode 11 has a step equal to or more than the thickness of the bonding layer 50 necessary for maintaining the bonding strength between the chip 10 and the conductor 70 in the first region 11a, the bonding strength between the chip 10 and the conductor 70 can be maintained. By adjusting a shape of the first region 11a and a supply amount of the material for forming the bonding layer 50, the bonding strength can be maintained.

The first metal layer ML1 contains, for example, Ti, and suppresses diffusion of atoms contained in the first electrode 11 into the substrate 20 to maintain the reliability of the semiconductor device 100. The second metal layer ML2 contains an element having higher solder wettability than that of the first electrode 11, and is provided between the first electrode 11 and the bonding layer 50, and thus it is possible to further increase the bonding strength of the bonding layer 50. Furthermore, by providing the second metal layer ML2 between the first electrode 11 and the bonding layer 50, for example, in a case where the first electrode 11 contains Cu and the bonding layer 50 includes solder, erosion of the first electrode 11 by the bonding layer 50 is suppressed. When the bonding layer 50 erodes the first electrode 11, the bonding layer 50 may contact the substrate 20. In addition, it is known that adhesion between the bonding layer 50 and the substrate 20 containing, for example, Si is lower than adhesion between the bonding layer 50 and the first electrode 11. According to the semiconductor device of the present embodiment, by suppressing contact between the bonding layer 50 and the substrate 20, a decrease in the bonding strength between the chip 10 and the conductor 70 is suppressed, and the reliability of the semiconductor device is improved.

### Modification of First Embodiment

FIG. 2 is a cross-sectional view of a semiconductor device 101 according to a modification of the first embodiment. Descriptions of portions common to the semiconductor device 100 illustrated in FIG. 1 will be omitted.

The first electrode 11 has a second region 11b separated from the first region 11a in the X direction and having a larger length in the X direction than that of the first region 11a. In other words, the first semiconductor region 21 is interposed between the first region 11a and the second region 11b in the X direction. The second region 11b is adjacent to the layer region 11L. The second region 11b extends in the substrate 20 and faces the first semiconductor region 21 in the X direction.

The length of the second region 11b in the X direction is, for example, 1.5 times or more the length of the first region 11a in the X direction. The length of the second region 11b in the X direction may be twice or more or three times or more the length of the first region 11a in the X direction. The length of the first region 11a in the X direction is, for example, 10 μm or more and less than 30 μm. The length of the second region 11b in the X direction is, for example, 30 μm or more and less than 60 μm.

Note that the length of the second region 11b is not necessarily larger than that of the first region 11a in the X direction, and may be larger in the Y direction. The length of the second region 11b is not necessarily different from the first region 11a in the X direction, and the second region 11b may be formed to extend to a position closer to the sixth semiconductor region 26 than the first region 11a. In order to suppress contact between the depletion layer and the first electrode 11 when the semiconductor device 100 is turned off, it is desirable that the first semiconductor region 21 is interposed between the second region 11b and the sixth semiconductor region 26. A distance between the first region 11a and the second electrode 12 and a distance between the second region 11b and the second electrode 12 in the Z direction are longer than a distance between the first semiconductor region 21 and the second electrode 12 in the Z direction.

For example, the sixth semiconductor region 26 is formed along the XY plane. Note that it is desirable that respective distances between the first region 11a and the sixth semiconductor region 26 and between the second region 11b and the sixth semiconductor region 26 are equal from the viewpoint of manufacturing efficiency because the first region 11a and the second region 11b can be simultaneously formed.

On the lower surface of the first electrode 11, the portion of the second region 11b is located further in the positive direction of the Z direction than the portion of the first region 11a. The lower surface of the first electrode 11 is a flat surface parallel to the XY plane in the portion of the second region 11b, for example, as illustrated in FIG. 2. The lower surface of the first electrode 11 may protrude in the negative direction of the Z direction in the portion of the second region 11b with a step smaller than the step in the portion of the first region 11a.

The thickness of the first electrode in the Z direction in the second region 11b is larger than the thickness of the layer region 11L in the Z direction. The thickness of the first electrode 11 in the Z direction in the first region 11a is larger than the thickness of the first electrode 11 in the Z direction in the second region 11b at least partially.

According to the semiconductor device 101 of the present modification, it is possible to further improve a trade-off between heat dissipation and bonding strength. Since the second region 11b having a large width in the X direction is provided, the heat dissipation can be improved by using the second region 11b having a higher thermal conductivity than that of the substrate 20 as a heat dissipation path. On the other hand, under the second region 11b, since the thickness of the bonding layer 50 in the Z direction is larger than that of the first region 11a, the bonding strength between the chip 10 and the conductor 70 can be firmly maintained.

For comparison, if the heat dissipation is improved by the first region 11a, as the first region 11a is provided more or densely, an area of the region having a small thickness of the bonding layer 50 in the Z direction or the ratio of an area in the semiconductor device increases. On the other hand, according to the present modification, the heat dissipation is improved by the second region 11b having a higher thermal conductivity than that of the substrate 20, and the bonding layer 50 can also be provided to be thicker in the Z direction below the second region 11b than below the first region 11a. Therefore, it is possible to further improve a trade-off between heat dissipation and bonding strength.

### Second Embodiment

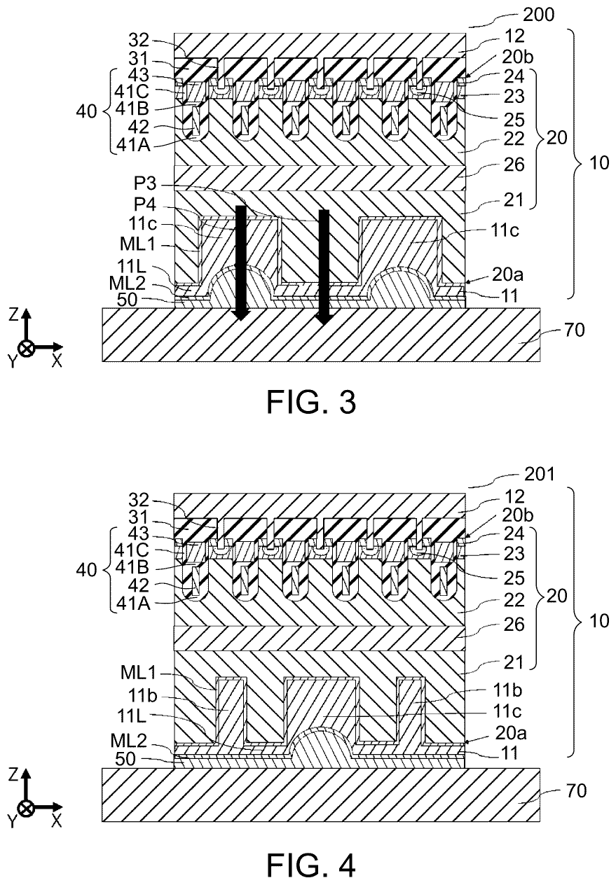

FIG. 3 is a cross-sectional view of a semiconductor device 200 according to a second embodiment. Descriptions of portions common to the semiconductor device 100 illustrated in FIG. 1 will be omitted.

The first electrode 11 of the semiconductor device 200 has a third region 11c extending in the substrate 20 from the first main surface 20a toward the second electrode 12, and a layer region 11L provided along the first main surface 20a of the substrate 20 adjacent to the third region 11c. The lower surface of the first electrode 11 is recessed in the positive direction of the Z direction in the third region 11c, and the lower surface is flat in the layer region 11L. The first electrode 11 is formed to be thicker in the Z direction in the third region 11c than the layer region 11L.

The length of the third region 11c in the X direction is, for example, 60 μm or more and half or less of the length of the chip 10 in the X direction. If the length of the chip 10 in the X direction is, for example, 3 mm, the length of the third region 11c in the X direction is 1.5 mm or less. In addition, the length of the chip 10 in the Y direction may be, for example, equal to the length of the chip 10 in the X direction, and the length of the third region 11c in the X direction is half or less of the length of the chip 10 in the Y direction.

Below the third region 11c, the bonding layer 50 is provided to be thicker than below the layer region 11L. At least a part of the upper surface of the bonding layer 50 below the third region 11c is located further in the positive direction of the Z direction than the upper surface of the bonding layer 50 below the layer region 11L.

According to the semiconductor device 200 of the present embodiment, by providing the third region 11c having a higher thermal conductivity than that of the substrate 20 above the region where the bonding layer 50 is provided to be thick in the Z direction, it is possible to improve a trade-off between heat dissipation and bonding strength.

By forming the bonding layer 50 to be thick below the third region 11c, the bonding strength between the chip 10 and the conductor 70 can be improved. In addition, the thickness of the bonding layer 50 in the Z direction below the third region 11c can be controlled by controlling a shape of the recess in the lower surface of the first electrode 11 formed in the third region 11c and adjusting a supply amount of the material of the bonding layer 50. Therefore, the semiconductor device can be designed to satisfy the required bonding strength.

By maintaining the bonding strength below the third region 11c, the bonding layer 50 below the layer region 11L can be formed to be thin in the Z direction. By forming the bonding layer 50 having a relatively low thermal conductivity to be thin below the layer region 11L, it is possible to increase the thermal conductance and improve the heat dissipation in a path P3 of the heat flow from the layer region 11L to the conductor 70 through the bonding layer 50.

Furthermore, if the third region 11c is located above the portion where the bonding layer 50 is provided to be thick, and the third region 11c has a higher thermal conductivity than that of the substrate 20, heat dissipation can be improved. That is, in a path P4, the bonding layer 50 is thick, but it is possible to suppress a decrease in thermal conductance since the path P4 passes through the third region 11c.

### Modification of Second Embodiment

FIG. 4 is a cross-sectional view of a semiconductor device 201 according to a modification of the second embodiment. Descriptions of portions common to the semiconductor device 200 illustrated in FIG. 3 will be omitted.

The first electrode 11 has a second region 11b separated from the third region 11c in the X direction. In other words, the first semiconductor region 21 is interposed between the second region 11b and the third region 11c in the X direction. The second region 11b is provided adjacent to the layer region 11L. In the second region 11b, at least a part of the lower surface of the first electrode 11 is located in the negative direction of the Z direction than relative to the third region 11c. In the second region 11b, the lower surface of the first electrode 11 is, for example, a flat surface parallel to the XY plane. In the second region 11b, the lower surface of the first electrode 11 may have a step smaller than the step in the third region 11c, and may have a structure recessed in the positive direction of the Z direction.

The length of the second region 11b in the X direction is smaller than the length of the third region 11c in the X direction. The length of the third region 11c in the X direction is, for example, 1.5 times or more the length of the second region 11b in the X direction. The length of the third region 11c in the X direction may be, for example, twice or more the length of the second region 11b in the X direction. The length of the second region 11b in the X direction is, for example, 30 μm or more and less than 60 μm. The length of the third region 11c in the X direction is, for example, 60 μm or more and half or less of the length of the chip 10 in the X direction.

The length of the second region 11b is not necessarily smaller than that of the third region 11c in the X direction, and may be smaller in the Y direction. The length of the second region 11b is not necessarily different from the third region 11c in the X direction, and the second region 11b may be provided farther from the sixth semiconductor region 26 than the third region 11c. For example, the sixth semiconductor region 26 is formed along the XY plane. Note that it is desirable that respective distances between the second region 11b and the sixth semiconductor region 26 and between the third region 11c and the sixth semiconductor region 26 are equal from the viewpoint of manufacturing efficiency because the second region 11b and the third region 11c can be simultaneously formed.

The bonding layer 50 below the second region 11b is provided to be thinner in the Z direction than the bonding layer 50 below the third region 11c. The bonding layer 50 below the second region 11b may be provided to be thicker or thinner in the Z direction than the bonding layer 50 below the layer region 11L.

According to the semiconductor device 201 of the present modification, heat dissipation can be further improved. Since the second region 11b is made of a material having a higher thermal conductivity than that of the substrate 20, the thermal conductance in the path of the heat flow passing through the second region 11b can be increased compared with a case where the second region 11b is not provided.

On the other hand, below the second region 11b, the bonding layer 50 having a relatively low thermal conductivity is provided to be thinner in the Z direction than below the third region 11c, and thus a decrease in thermal conductance is suppressed. Therefore, the heat dissipation path passing through the second region 11b is improved in heat dissipation.

The bonding strength between the chip 10 and the conductor 70 can be maintained by the bonding layer 50 provided to be thick below the third region 11c. By controlling a size of the step of the lower surface of the first electrode 11 in the third region 11c and controlling a thickness of the bonding layer 50 in the Z direction below the layer region 11L, it is possible to determine a thickness of the bonding layer 50 in the Z direction below the third region 11c and maintain the bonding strength.

### Third Embodiment

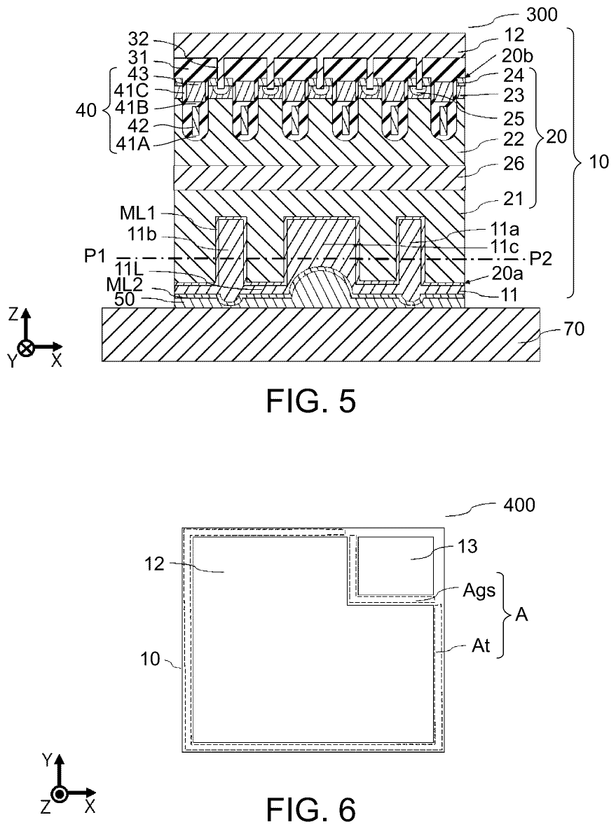

FIG. 5 is a cross-sectional view of a semiconductor device 300 according to a third embodiment. Descriptions of portions common to the semiconductor devices 100 and 200 illustrated in FIGS. 1 and 3 will be omitted.

The semiconductor device 300 includes a first region 11a and a third region 11c separated from the first region 11a in the X direction. The semiconductor device 300 has a structure in which the lower surface of the first electrode 11 protrudes in the negative direction of the Z direction in the first region 11a and is recessed in the positive direction of the Z direction in the third region 11c. The length of the first region 11a in the X direction is smaller than the length of the third region 11c in the X direction.

Note that the length of the first region 11a is not necessarily smaller than that of the third region 11c in the X direction, and may be smaller in the Y direction. The length of the first region 11a is not necessarily different from the third region 11c in the X direction, and the first region 11a may be provided farther from the sixth semiconductor region 26 than the third region 11c. For example, the sixth semiconductor region 26 is formed along the XY plane. Note that it is desirable that respective distances between the first region 11a and the sixth semiconductor region 26 and between the third region 11c and the sixth semiconductor region 26 are equal from the viewpoint of manufacturing efficiency because the first region 11a and the third region 11c can be simultaneously formed.

The first electrode 11 further includes a layer region 11L adjacent to the first region 11a and the third region 11c, and the thickness of the bonding layer 50 in the Z direction below the third region 11c is larger than the thickness of the bonding layer 50 in the Z direction below the layer region 11L. The thickness of the bonding layer 50 in the Z direction below the layer region 11L is larger than the thickness of the bonding layer 50 in the Z direction below the first region 11a. The bonding layer 50 is not necessarily provided on the entire upper surface of the conductor 70, and the first region 11a may be in direct contact with the conductor 70 via the second metal layer ML2.

According to the semiconductor device 300 of the present embodiment, the heat dissipation can be improved, and the bonding strength between the chip 10 and the conductor 70 can be improved. The heat dissipation is improved by improving the thermal conductance in the path of the heat flow passing through the first region 11a. By forming the bonding layer 50 below the third region 11c to be thick in the Z direction, the bonding strength between the chip 10 and the conductor 70 is improved.

Compared with the semiconductor device 100 according to the first embodiment, in the present embodiment, the heat dissipation can be further improved by reducing the thickness of the bonding layer 50 in the Z direction below the layer region 11L. Even if the bonding layer 50 below the layer region 11L is formed to be thin in the Z direction, since the bonding layer 50 below the third region 11c is formed to be thick in the Z direction, the bonding strength between the chip 10 and the conductor 70 can be maintained.

The thickness of the bonding layer 50 in the Z direction below the layer region 11L can be widely selected. Even if the thickness of the bonding layer 50 in the Z direction below the layer region 11L is about the same as the step of the structure of the lower surface of the first electrode 11 in the first region 11a protruding in the negative direction of the Z direction, the bonding strength between the chip 10 and the conductor 70 can be maintained. Therefore, it is not necessary to interpose the bonding layer 50 between the first region 11a and the conductor 70. The thermal conductance can be further improved by the path of the heat flow in which the bonding layer 50 is not interposed.

Compared with the semiconductor device 200 according to the second embodiment, in the present embodiment, heat dissipation can be improved by forming the bonding layer 50 below the first region 11a to be thin. The thickness of the bonding layer 50 in the Z direction below the layer region 11L can be widely selected in the present embodiment and the second embodiment. In the present embodiment, by further forming the first region 11a, the bonding layer 50 can be formed to be thinner in the Z direction below the first region 11a than below the layer region 11L, and the heat dissipation can be improved.

### Fourth Embodiment

FIGS. 6, 7, and 8 are top views illustrating a semiconductor device according to a fourth embodiment. FIGS. 6, 7, and 8 are views of a chip 10 when viewed from the positive direction of the Z direction. A second electrode 12 provided on the upper surface of the chip 10 and a third electrode 13 separated from the second electrode 12 are illustrated. The second electrode 12 is, for example, a source electrode. The third electrode 13 is, for example, a gate pad. First, a description will be made with reference to FIG. 6.

A semiconductor device 400 illustrated in FIG. 6 is an example in which the third electrode 13 is provided at one corner of the chip 10, and the second electrode 12 is provided apart from the third electrode 13 in the X direction and the Y direction. The third electrode 13 is not limited to be provided at the corner of the chip, and may be located at the end of the chip.

Here, a boundary region A in which heat dissipation is likely to deteriorate is generally defined. The boundary region A is a region that is defined on the chip 10 in the XY plane and does not overlap the second electrode 12 and the third electrode 13 in the Z direction. Since the second electrode 12 and the third electrode 13 are main heat dissipation paths of the heat flow on the upper surface of the chip 10, in general, the heat dissipation of the boundary region A is likely to deteriorate.

The boundary region A includes a termination region At which is an end portion of the chip 10 and is located at a peripheral edge of the second electrode 12, and an inter-electrode region Ags which is a space between the second electrode 12 and the third electrode 13. The inter-electrode region Ags includes a first portion extending in the X direction and a second portion extending in the Y direction.

The semiconductor device 400 according to the present embodiment has a structure in which heat dissipation from the lower surface of the chip 10 is improved at a position corresponding to the boundary region A. Taking the semiconductor device 100 as an example, the first region 11a of the first electrode 11 is formed on the lower surface of the chip 10 at a position corresponding to the boundary region A in the negative direction of the Z direction. A path P1 of the heat flow passing through the first region 11a in the boundary region A is a heat dissipation path having large thermal conductance.

The first region 11a formed at the position corresponding to the boundary region A is provided to surround the second electrode 12 along the termination region At, for example. The first regions 11a may be formed in a plurality of rows by extending along the termination region At to multiply surround the second electrodes 12. Also in the inter-electrode region Ags, a plurality of rows of the first regions 11a are formed along the inter-electrode region Ags, for example. Although the first region 11a is not necessarily formed along the boundary region A, in order to provide the first region 11a to be wider at the position corresponding to the boundary region A, it is desirable to form the first region 11a along the boundary region A.

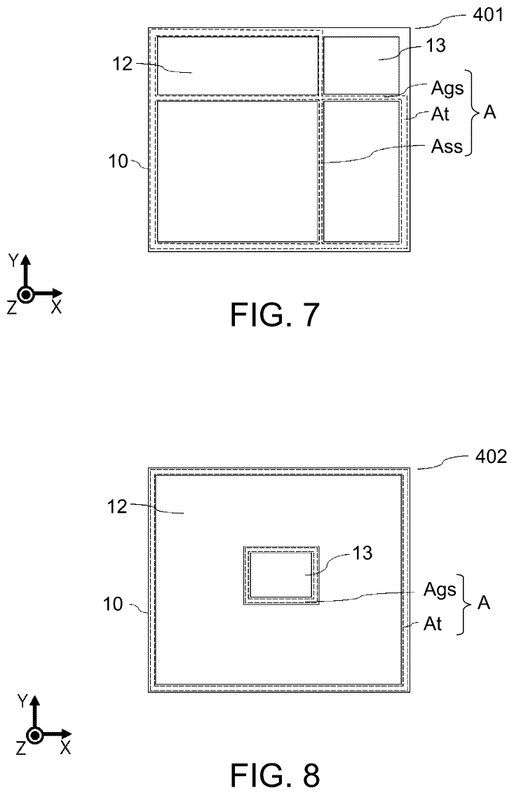

As illustrated in a semiconductor device 401 in FIG. 7, a plurality of second electrodes 12 may be formed. The boundary region A may further include an inter-electrode region A is located between the second electrodes 12. The first regions 11a are provided in one row or a plurality of rows extending along the inter-electrode region As, for example.

Furthermore, as illustrated in a semiconductor device 402 in FIG. 8, the third electrode does not need to be located at the end of the chip 10, and may be provided at the central portion of the chip 10. Here, a central portion of a certain region is a region located at the center of the region on the XY plane. The third electrode 13 is surrounded by the second electrode 12. The inter-electrode region Ags is located, for example, in a ring shape. The first regions 11a are formed in a plurality of rows extending along, for example, the inter-electrode region Ags to multiply surround the third electrodes 13.

The structure in which the first region 11a of the first electrode 11 is formed on the lower surface of the chip 10 at the position corresponding to the boundary region A in the negative direction of the Z direction is not limited to the semiconductor device 100, and can also be applied to the semiconductor device 101 having the second region 11b in addition to the first region 11a or the semiconductor device 300 having the third region 11c in addition to the first region 11a. Also in the semiconductor device 101 or 300, the first region 11a of the first electrode 11 can be formed on the lower surface of the chip 10 at the position corresponding to the boundary region A.

Furthermore, in the case of the semiconductor device 201 illustrated in FIG. 4, the second region 11b is formed at the position corresponding to the boundary region A in the negative direction of the Z direction. The second region 11b extends along, for example, the termination region At to surround the second electrode 12, and is formed in one row or a plurality of rows. Also in the inter-electrode region Ags, the second region 11b is formed in a plurality of rows along the inter-electrode region Ags, for example. That is, a region provided at the position corresponding to the boundary region A is not necessarily the first region 11a, and may be the second region 11b.

According to the semiconductor device 400 of the present embodiment, the reliability of the semiconductor device can be improved by improving the heat dissipation in the boundary region A. In the boundary region A, for example, the path P1 of the semiconductor device 100 is used as a path of the heat flow to increase thermal conductance and improve heat dissipation. In general, by improving the heat dissipation in the boundary region A where the heat dissipation may deteriorate due to the absence of an electrode on the upper surface of the chip 10, local accumulation of heat in the chip 10 is suppressed, and thermal destruction is suppressed.

Taking the semiconductor device 100 as an example, the heat dissipation of the boundary region A can be improved by providing the first region 11a in the boundary region A, and the layer region 11L can be provided in an area sufficient for maintaining the bonding strength between the chip 10 and the conductor 70 in a region other than the boundary region A, for example, the central portion of the chip 10. In the central portion of the chip 10, the bonding layer 50 below the layer region 11L maintains the bonding strength between the chip 10 and the conductor 70.

Furthermore, in the semiconductor device 101, the first region 11a can be provided in the boundary region A, and the second region 11b can be provided in the central portion of the chip 10. Therefore, compared with the semiconductor device 100 having the first region 11a and the layer region 11L, the heat dissipation in the central portion of the chip 10 can be improved by providing the second region 11b having thermal conductance larger than that of the layer region 11L in the central portion of the chip 10. Furthermore, in the semiconductor device 300, by providing the third region 11c in the central portion of the chip, the bonding strength at the central portion of the chip 10 can be further improved.

In the semiconductor device 201, for example, by providing the second region 11b at the position corresponding to the boundary region A, the thermal conductance is increased in the path of the heat flow passing through the second region 11b containing the material having the thermal conductivity higher than that of the substrate 20, and the heat dissipation of the boundary region A is improved. On the other hand, the bonding strength between the chip 10 and the conductor 70 can be maintained by providing the third region 11c at a position corresponding to a region other than the boundary region A, for example, at a position corresponding to the central portion of the chip 10.

### Fifth Embodiment

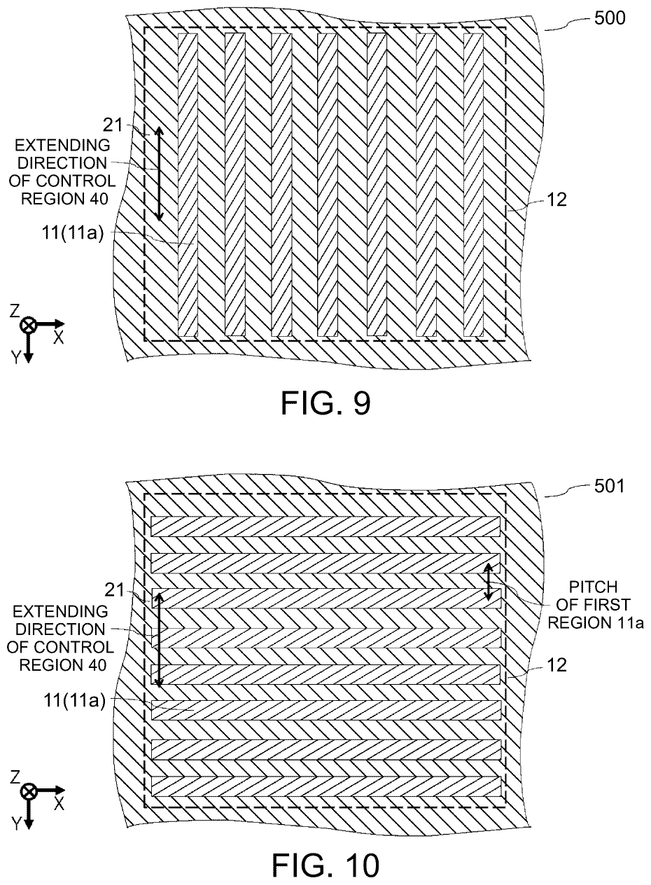

FIG. 9 is a cross-sectional view along an XY plane illustrating a semiconductor device 500 according to a fifth embodiment. FIG. 9 is a view of a cross section in an XY plane taken along line P1-P2 illustrated in FIG. 5 when viewed from the negative direction of the Z direction. The first electrode 11 provided in the first semiconductor region 21 of the substrate 20 is illustrated. The second electrode 12 overlapping in the positive direction of the Z direction is illustrated as a region surrounded by a dashed line. FIG. 9 illustrates an example in which the second electrode 12 has a rectangular shape on the XY plane, but a shape of the second electrode 12 is not limited to a rectangular shape.

FIGS. 9 to 11 illustrate a part of the first semiconductor region 21 overlapping the second electrode 12 in the Z direction, and do not illustrate, for example, a portion overlapping the third electrode 13 in the Z direction. However, on the upper surface of the chip 10, the third electrode 13 (not illustrated) may be provided apart from the second electrode 12 indicated by the dashed line, and another second electrode 12 (not illustrated) may be further provided. That is, although not illustrated in FIG. 9, for example, the inter-electrode regions Ags and Ass or the termination region At illustrated in FIG. 7 may be located around the second electrode 12.

A plurality of first regions 11a of the first electrode 11 are arranged in the X direction and extend in the Y direction. Although not illustrated in FIG. 9, a plurality of control regions 40 are arranged in the X direction on the upper surface of the substrate 20 and extend in the Y direction. An extending direction of the control region 40 is indicated by an arrow in the Y direction in FIG. 9. The first region 11a is provided to extend in the direction in which the control region 40 extends. In FIG. 9, the third region 11c is not shown.

Since channels formed in the third semiconductor region 23 by a voltage applied to the gate electrode 43 are formed along the control regions 40, a plurality of channels is arranged in the X direction and extend in the Y direction. When the semiconductor device is in an ON state, a current mainly flows through a portion where a channel is formed in a region overlapping the second electrode 12 surrounded by the dashed line in the Z direction. That is, when the semiconductor device is in an ON state, a plurality of portions where a current flows and heat is generated are arranged in the X direction and extend in the Y direction.

The first region 11a of the first electrode 11 is provided in the X direction between the control regions 40 adjacent in the X direction on the upper surface of the substrate 20, and desirably overlaps the channel formed in the third semiconductor region 23 in the Z direction. The wider the portion where the channel formed in the third semiconductor region 23 and the first region 11a of the first region 11 overlap in the Z direction, the more the heat dissipation is improved with respect to heat generated from the channel.

In addition, the first electrode 11 illustrated in FIG. 9 is not limited to the case of having the first region 11a, and may have the third region 11c. The third regions 11c are arranged in the X direction and provided to extend in the Y direction. In this case, the path P3 illustrated in FIG. 3 extends in the Y direction which is the extending direction of the control region 40.

According to the semiconductor device 500 of the present embodiment, the heat dissipation of the semiconductor device can be further improved. The bonding layer 50 below the first region 11a is formed to be thinner than the other regions, and the path of the heat flow passing through the first region 11a has large thermal conductance. By providing the first region 11a in the direction in which the channel is formed, heat generated mainly in the channel through which the current flows can be efficiently dissipated to the conductor 70.

In an ON state of the semiconductor device, heat generated from the channel when the current is flowing through the channel is dissipated through the first region 11a, so that thermal destruction of the semiconductor device can be suppressed.

According to the semiconductor device of the present embodiment, since the first region 11a extending in the Y direction can dissipate heat generated in the channel extending in the Y direction, heat dissipation can be improved. For each position in the Y direction in which the channel generates heat, the first region 11a extending in the Y direction serves as a heat dissipation path and suppresses local accumulation of heat.

If the first electrode 11 has the third region 11c, as described with reference to FIG. 3, the path P3 serving as a heat dissipation path having a large thermal conductance extends in the direction in which the channel extends, and thus the heat dissipation of the semiconductor device via the path P3 can be improved.

### First Modification of Fifth Embodiment

FIG. 10 is a cross-sectional view taken along an XY plane of a semiconductor device 501 according to a first modification of the fifth embodiment. As illustrated in FIG. 10, the first region 11a may extend in a direction orthogonal to the extending direction of the control region 40. The first regions 11a extend in the X direction and are formed side by side in the Y direction.

A length of one cycle of the cyclically arranged structures is defined as a pitch. A pitch in the Y direction of the first regions 11a illustrated in FIG. 10 is a length between the centers of the first regions 11a adjacent to each other in the Y direction. A pitch in the X direction of the control regions 40 arranged in the X direction may be different from a pitch in the Y direction of the first regions 11a arranged in the Y direction. For example, the pitch of the control region 40 in the X direction is smaller than the pitch of the first region 11a in the Y direction.

In addition, the extending direction of the first region 11a does not need to be orthogonal to the extending direction of the control region 40, and may intersect. When the semiconductor device 501 is in an ON state, a plurality of channels extending in the Y direction and arranged in the X direction and the first region 11a do not need to be orthogonal to each other, and may intersect each other.

According to the semiconductor device 501 of the present modification, even if the pitch of the control region 40 in the X direction is different from the pitch of the first region 11a in the Y direction, heat generated in the channel when the semiconductor device is in an ON state can be efficiently dissipated by the first region 11a.

Each of the first regions 11a extending in the X direction overlaps in the Z direction with a plurality of channels extending in the Y direction and arranged in the X direction. That is, each of the first regions 11a extending in the X direction serves as a heat dissipation path from the plurality of channels.

Each of the plurality of channels arranged in the X direction and the first region 11a extending in the X direction at least partially overlap each other in the Z direction. Therefore, the heat dissipation paths are uniformly provided for the plurality of respective channels arranged in the X direction. Even if the pitch of the control region 40 in the X direction is smaller than the pitch of the first region 11a, it is possible to suppress the heat dissipation from being different among the plurality of channels.

For comparison, in the example of the semiconductor device 500 illustrated in FIG. 9, in a case where the pitch in the X direction of the control region 40 is smaller than the pitch of the first region 11a in the X direction in the semiconductor device 500, a region having large thermal conductance and a region having small thermal conductance may be generated in the XY plane. In a case where a plurality of control regions 40 are provided between the first regions 11a adjacent in the X direction, for heat generated from a channel near the middle of the first regions 11a adjacent in the X direction, heat dissipation may be inferior to a portion closer to the first regions 11a. That is, for a plurality of channels arranged in the X direction, a channel having an excellent heat dissipation and a channel having a poor heat dissipation may be locally present.

On the other hand, according to the semiconductor device 501 of the present modification, even if the pitch of the control region 40 in the X direction is smaller than the pitch of the first region 11a in the Y direction, the heat dissipation of each of the plurality of channels arranged in the X direction can be more uniformly improved. It is possible to suppress the occurrence of a portion locally having a poor heat dissipation and to further improve the reliability of the semiconductor device.

That is, according to the semiconductor device 500 illustrated in FIG. 9, by uniformly improving the heat dissipation in the Y direction for each of the channels extending in the Y direction, it is possible to suppress the occurrence of a portion locally having a poor heat dissipation in a single channel continuous in the Y direction. On the other hand, according to the semiconductor device 501 of the present modification, it is possible to suppress the occurrence of a portion locally having a poor heat dissipation between the plurality of channels arranged in the X direction. In any case, it is possible to suppress the occurrence of a portion locally having a poor heat dissipation and to improve the reliability of the semiconductor device.

Furthermore, according to the semiconductor device 501 of the present modification, the reliability of the semiconductor device can be further improved by reducing the warpage of the chip 10. A trench is provided in the Z direction in each of the first main surface 20a and the second main surface 20b on the substrate 20 of the chip 10. When the trenches provided in the first main surface 20a and the second main surface 20b intersect (desirably, orthogonal to) each other, the warpage of the chip 10 can be reduced.

In general, in a case where a trench extending in one direction (for example, the Y direction) is provided on the second main surface 20b of the substrate 20 and a material for forming the control region 40 is embedded in the trench, a stress distribution applied to the substrate 20 is different between a direction along the trench (Y direction) and a direction orthogonal to the trench (X direction). The difference in the stress distribution between the X direction and the Y direction may cause warpage of the substrate 20 and the chip 10. When the chip 10 is warped, for example, an air layer having a low thermal conductivity can be formed in the bonding layer 50 including solder, and the heat dissipation of the chip 10 may deteriorate and cause thermal destruction.

In the present modification, a trench extending in a direction intersecting (desirably orthogonal to) the trench provided on the second main surface 20b is provided in the first main surface 20a of the substrate 20, and a material for forming the first electrode 11 is embedded in the trench. When the trenches intersect, stress distributions in the X direction and the Y direction on the first main surface 20a of the substrate 20 are generated in a direction in which a difference in stress distributions between the X direction and the Y direction on the second main surface 20b is alleviated. Therefore, for example, compared with a case where a trench extending in the same direction as the trench provided on the second main surface 20b is provided on the first main surface 20a, it is possible to suppress the warpage of the chip 10 by suppressing the bias of the stress distributions in the X direction and the Y direction in the chip 10. By suppressing the warpage of the chip 10, it is possible to suppress the formation of an air layer having a low thermal conductivity in the bonding layer 50 and the like and to improve the reliability by maintaining a favorable heat dissipation.

### Second Modification of Fifth Embodiment

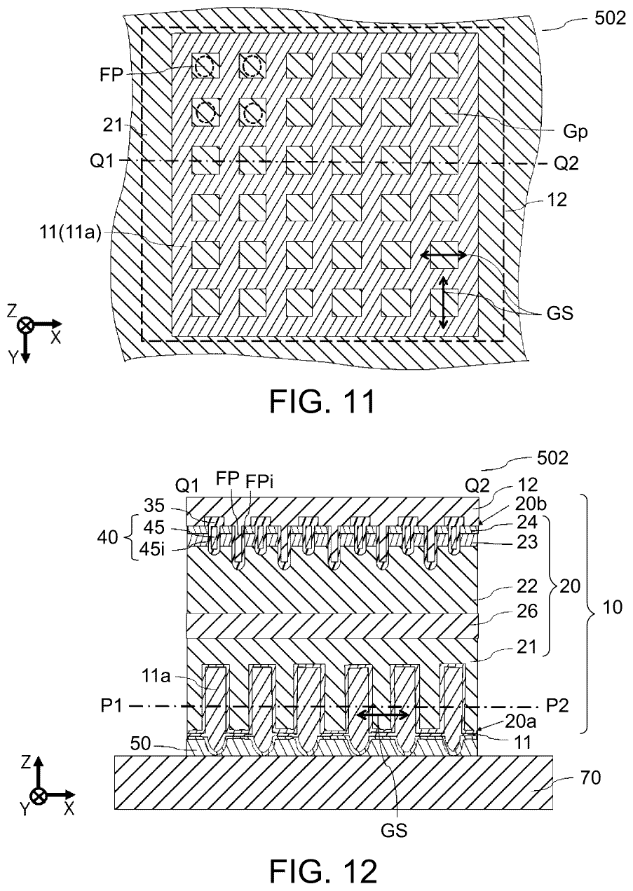

FIG. 11 is a cross-sectional view along an XY plane of a semiconductor device 502 according to a second modification of the fifth embodiment. FIG. 11 is a view of a cross section in the XY plane taken along line P1-P2 illustrated in FIG. 5 when viewed from the negative direction of the Z direction. Descriptions of portions common to the semiconductor device 500 will be omitted.

FIG. 11 illustrates an example in which the first region or regions 11a of the first electrode 11 are provided in a grid shape extending in the X direction and the Y direction. A width in the Y direction of the portion extending in the X direction in the first region 11a may be different from a width in the X direction of the portion extending in the Y direction in the first electrode 11. A pitch in the Y direction of the portion extending in the X direction in the grid shape and a pitch in the X direction of the portion extending in the Y direction in the grid shape are, for example, equal, and hereinafter, simply referred to as a grid interval. That is, the grid interval is commonly defined in the X direction and the Y direction, and is a length between centers of adjacent portions extending in parallel in the grid shape. For example, the grid interval of the first region 11a of the first electrode 11 is a length GS illustrated in FIG. 11.

An example in which the first region 11a extends in the X direction and the Y direction, and the first region 11a of the first electrode 11 is formed in a grid shape on the XY plane will be described. That is, a heat dissipation path passing through the grid-shaped first region 11a is a heat dissipation path having a large thermal conductance.

On the upper surface of the substrate 20 not illustrated in FIG. 11, the control region 40 is provided in a grid shape extending in the X direction and the Y direction, for example. Not limited to the case of the grid shape, the control region 40 may include at least a portion extending in the X direction and a portion extending in the Y direction. Furthermore, the control region 40 may include at least a portion extending in the Y direction as illustrated in FIG. 9 or 10, for example. The control region 40 may include at least a portion extending in the X direction.

The grid interval of the first region 11a of the first electrode 11 and the grid interval of the control region 40 may be different, but a case where the grid interval of the first region 11a of the first electrode 11 and the grid interval of the control region 40 are equal is desirable because heat dissipation is further improved as will be described later.

The semiconductor device 502 according to the present modification includes a field plate FP provided in a dot shape on the second main surface 20b side of the substrate 20 while being separated in the X direction and the Y direction. A cross-sectional shape of the field plate FP on the XY plane is, for example, a circular shape. A cross-sectional shape of the field plate FP on the XY plane may be a rectangular shape.

FIG. 12 is an XZ cross-sectional view taken along line Q1-Q2 illustrated in FIG. 11. A structure on the second main surface 20b side of the substrate 20 is different from that of the semiconductor device 100.

The control region 40 includes a gate electrode 45 and a gate insulating film 45i interposed between the gate electrode 45 and the substrate 20. An insulating layer 35 is interposed between the gate electrode 45 and the second electrode 12.

The field plate FP is provided apart from the control region 40 in the X direction, and an insulating portion FPi is interposed between the field plate FP and the substrate 20. The field plate FP is electrically connected to the second electrode 12.

The third semiconductor region 23 (p-type base region) and the fourth semiconductor region 24 (n⁺-type source region) provided on the third semiconductor region 23 are provided between the control region 40 and the insulating portion FPi in the X direction. Although not illustrated in FIG. 12, a p⁺-type contact region may be further provided on the third semiconductor region 23 to be connected to the second electrode 12.

The field plate FP extends in the negative direction of the Z direction in the substrate 20 from the second main surface (upper surface) 20b of the substrate 20. The field plate FP is, for example, conductive polysilicon containing impurities, and the insulating portion FPi includes, for example, an insulator such as silicon oxide.

FIG. 12 illustrates an example in which the grid interval of the first region 11a of the first electrode 11 is equal to the grid interval of the control region 40. Note that although FIG. 12 illustrates the XZ cross section, the semiconductor device 501 may have a similar structure in the YZ cross section. The first region 11a is provided at a position overlapping, in the Z direction, each of the control regions 40 arranged in the X direction. Note that a length of each of the control regions 40 in the X direction and the length of each of the first regions 11a in the X direction may be different. For example, the first region 11a may be formed to be longer in the X direction, and at least a part of the third semiconductor region 23 and the fourth semiconductor region 24 adjacent to the control region 40 and the first region 11a may overlap in the Z direction. That is, a portion where a channel is mainly formed when the semiconductor device 502 is in an ON state overlaps the first region 11a in the Z direction.

The first region 11a may be provided at a position overlapping, in the Z direction, each of the field plates FP arranged in the X direction. In addition, the grid interval of the first region 11a of the first electrode 11 and the grid interval of the control region 40 may be different.

An operation of the semiconductor device 502 will be described with reference to FIGS. 11 and 12. When a voltage is applied to the gate electrode 45 of the control region 40, a channel is formed in the third semiconductor region 23 adjacent to the control region 40. The channel has a portion extending in the X direction and a portion extending in the Y direction along the grid shape of the control region 40. The channel is formed to surround the field plate FP between the control regions 40 having a grid shape, for example. When the semiconductor device 502 is turned off, a depletion layer extends from the insulating portion FPi of the field plate FP to the second semiconductor region 22 to maintain a breakdown voltage.

According to the semiconductor device 502 of the present modification, if the control regions 40 are provided in, for example, a grid shape, heat generated by a current flowing through a channel including a portion extending in each of the X direction and the Y direction can be efficiently dissipated by the first regions 11a of the first electrode 11 provided in a grid shape.

Since the first regions 11a of the first electrode 11 are provided in a grid shape, heat generated from the portion extending in the X direction in the channel is dissipated through the portion of the first region 11a extending in the X direction. In addition, the heat dissipation of a plurality of channels arranged in the Y direction is improved via the portion of the first region 11a of the first electrode 11 extending in the Y direction. On the other hand, heat generated from the portion extending in the Y direction in the channel is dissipated via the portion of the first region 11a of the first electrode 11 extending in the Y direction, and the heat dissipation of the plurality of channels arranged in the X direction is improved via the portion of the first region 11a of the first electrode 11 extending in the X direction. That is, it is possible to suppress accumulation of heat due to local deterioration in the heat dissipation and improve reliability of the semiconductor device.

When the grid interval of the first region 11a of the first electrode 11 is equal to the grid interval of the control region 40, the portion where the channel formed around the control region 40 and the first region 11a of the first electrode 11 overlap in the Z direction increases, so that the heat dissipation can be further improved.

Even if the control region 40 does not have a grid shape, the heat dissipation can be improved. For example, in a case where the control regions 40 extend in the Y direction and are arranged in the X direction, the first regions 11a of the first electrodes 11 provided in a grid shape have a portion in the extending direction of the control regions 40 and a portion intersecting the extending direction of the control regions 40. Therefore, as described for the semiconductor devices 500 and 501, it is possible to suppress the occurrence of a portion where heat dissipation locally deteriorates in the channel formed in the extending direction of the control region 40 and to improve the reliability of the semiconductor device.

For example, if the control regions 40 extend in the Y direction and are arranged in the X direction, the first regions 11a of the first electrode 11 provided in a grid shape improve the heat dissipation for each of the channels extending in the Y direction, thereby suppressing the occurrence of a portion where heat dissipation locally deteriorates in a single channel continuous in the Y direction. Furthermore, it is possible to suppress the occurrence of a portion where heat dissipation locally deteriorates between the plurality of channels arranged in the X direction.

### Sixth Embodiment

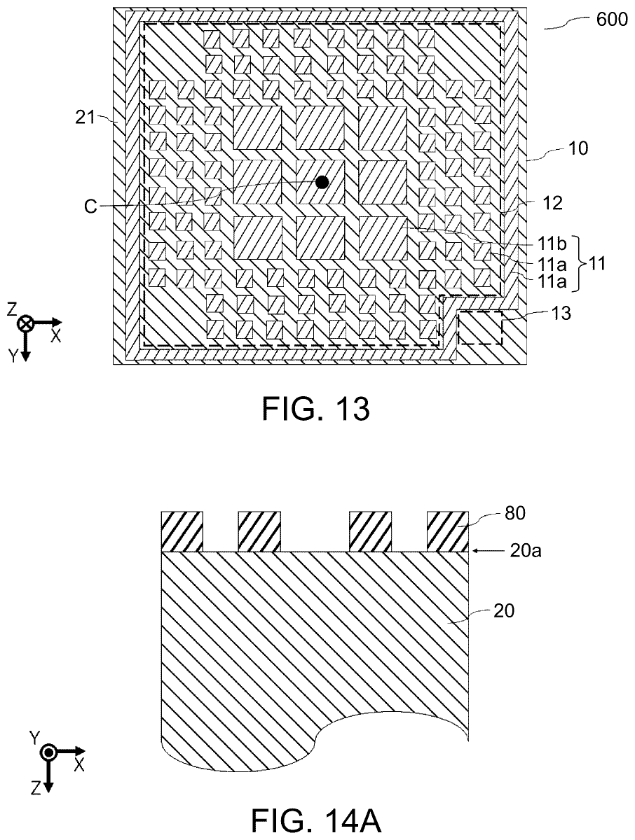

FIG. 13 is a cross-sectional view along an XY plane illustrating a semiconductor device 600 according to a sixth embodiment. FIG. 13 is a view of a cross section in the XY plane taken along line P1-P2 illustrated in FIG. 5 when viewed from the negative direction of the Z direction. Description of portions common to the semiconductor device 500 according to the fifth embodiment will be omitted.

FIG. 13 is a cross-sectional view of the entire chip 10. FIG. 13 illustrates the second electrode 12 and the third electrode 13 of the semiconductor device 400 illustrated in FIG. 6 as regions surrounded by dashed lines. An example is illustrated in which one row of first regions 11a is provided at positions overlapping the boundary region A (the termination region At and the inter-electrode region Ags) in the Z direction. Note that the first regions 11a may be formed in a plurality of rows. The center of the chip 10 on the XY plane is illustrated as a center C.

In a portion of the first electrode 11 surrounded by the first region 11a provided along the boundary region A on the XY plane, a plurality of first regions 11a and a plurality of second regions 11b are provided in a dot shape in each of the X direction and the Y direction. The first semiconductor region 21 of the substrate 20 is interposed in a grid shape between the first region 11a and the second region 11b of the first electrode 11. The second region 11b is provided in the central portion of the second electrode 12, the dot-shaped first regions 11a are provided around the at least one second region 11b, and the first regions 11a are further provided around the dot-shaped first regions 11a along the boundary region A.

The second regions 11b each have a larger cross-sectional area on the XY plane than that of the first region 11a provided in a dot shape. The second regions 11b may each have a larger length in the X direction or a larger length in the Y direction than that of the first region 11a provided in a dot shape.

FIG. 13 illustrates an example in which the first electrode 11 includes the first region 11a and the second region 11b as illustrated in FIG. 2. The second region 11b illustrated in FIG. 13 may be replaced with a third region 11c. Further, as illustrated in FIG. 4, the first electrode 11 may have the second region 11b and the third region 11c. In this case, for example, the third regions 11c are provided at the central portion of the second electrode 12 indicated by a dotted line, and the second regions 11b are provided to surround the third regions 11c on the XY plane.

The central portion of the second electrode 12 overlaps, for example, an active region of the chip 10, and is a portion through which a current mainly flows in an ON state of the semiconductor device. That is, when the semiconductor device is turned on, a heat generation value increases at the central portion of the second electrode 12. On the other hand, in a portion located to surround the central portion of the second electrode 12 and closer to the inter-electrode regions Ags and As or the termination region At than the central portion of the second electrode 12, a magnitude of the current in an ON state is smaller than that in the active region.

It is desirable that the dot-shaped first region 11a, the second region 11b, and the third region 11c are provided symmetrically in the XY plane in wider area. Here, being symmetric indicates being point symmetric with respect to a certain point. For example, it is desirable that there are many portions provided point-symmetrically with respect to the center C of the chip 10 in the XY plane. In the example illustrated in FIG. 13, the first region 11a is not provided in the vicinity of the corner of the portion overlapping the second electrode 12 of the chip 10, and the dot-shaped first region 11a and the second region 11b are provided in point symmetry with respect to the center C (the first region 11a overlapping the boundary region A in the Z direction is not necessarily provided symmetrically). On the other hand, among the corners of the chip 10, the first region 11a may be provided at the corner where the third electrode 13 is not provided, and the dot-shaped first region 11a is not necessarily point-symmetric with respect to the center C.

According to the semiconductor device 600 of the present embodiment, by providing the dot-shaped first region 11a surrounding the central portion of the second electrode 12, it is possible to improve the heat dissipation of the region having relatively poor heat dissipation in the chip 10. As described in the fourth embodiment, in addition to providing the first region 11a in the inter-electrode regions Ags and As or the termination region At, the dot-shaped first region 11a is also provided in the portion closer to the inter-electrode regions Ags and As or the termination region At than the central portion of the second electrode 12. In a region where an electrode is not provided on the upper surface of the chip 10 and a heat dissipation deteriorates, a path of heat dissipation to the conductor 70 via the first region 11a increases, and thermal conductance can be increased.

On the other hand, the bonding strength between the chip 10 and the conductor 70 can be improved by the bonding layer 50 (not illustrated in FIG. 13) below the second region 11b surrounded by the dot-shaped first region 11a. The bonding layer 50 located below the first electrode 11 is provided below the second region 11b to be thicker in the Z direction than below the first region 11a. Since the bonding layer 50 is provided to be thick below the second region 11b than below the first region 11a, the bonding strength between the chip 10 and the conductor 70 is improved. In a case where the second region 11b illustrated in FIG. 13 is replaced with the third region 11c, the bonding layer 50 is provided to be thicker, so that the bonding strength between the chip 10 and the conductor 70 is further improved.

Furthermore, according to the semiconductor device 600 of the present embodiment, the first region 11a, the second region 11b, and the third region 11c are symmetrically disposed, so that a stress applied to the substrate 20 can be reduced. In the portion where the first region 11a, the second region 11b, and the third region 11c are provided, the thickness of the first electrode 11 in the Z direction is larger than that of the layer region 11L. The thermal expansion coefficients of the first electrode 11 and the substrate 20 are different, and a distribution of the stress applied to the substrate 20 due to the thermal history depends on layouts of the first region 11a, the second region 11b, and the third region 11c. According to the semiconductor device of the present embodiment, the first electrode 11 can be provided in point symmetry with respect to the center C of the chip at least in a region other than the periphery of the third electrode 13. By providing many portions where the first region 11a, the second region 11b, and the third region 11c are symmetrically disposed and distributing the stress more isotropically in the XY plane, the substrate 20 is suppressed from being warped by the stress. The warpage of the substrate 20 can be suppressed to improve the reliability of the semiconductor device. Since the first electrode 11 can be disposed symmetrically by finely adjusting an area where the first region 11a is provided by providing the first electrode 11 in a dot shape, the semiconductor device 600 according to the present embodiment can be applied to various layouts of the second electrode 12 and the third electrode 13 on the XY plane.

According to the semiconductor device of at least one embodiment described above, heat dissipation can be improved by forming the bonding layer 50 below the first region 11a to be thin. Alternatively, the bonding strength between the chip 10 and the conductor 70 can be improved by increasing the thickness of the bonding layer 50 in the Z direction below the third region 11c. By disposing the first region 11a, the second region 11b, and the third region 11c in combination, it is possible to provide a semiconductor device with improved heat dissipation and bonding strength.

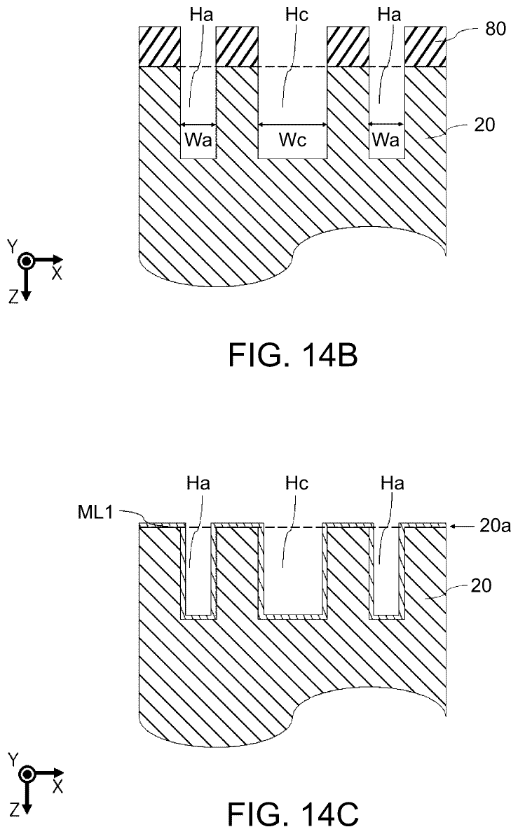

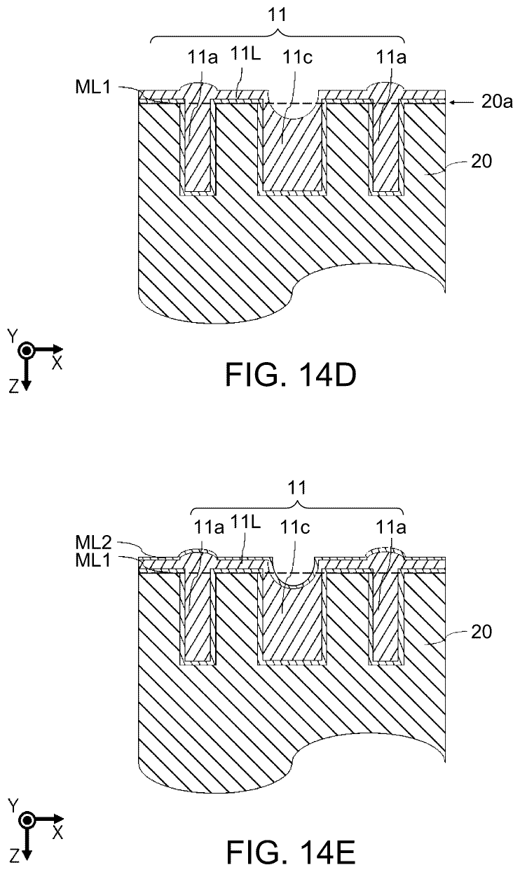

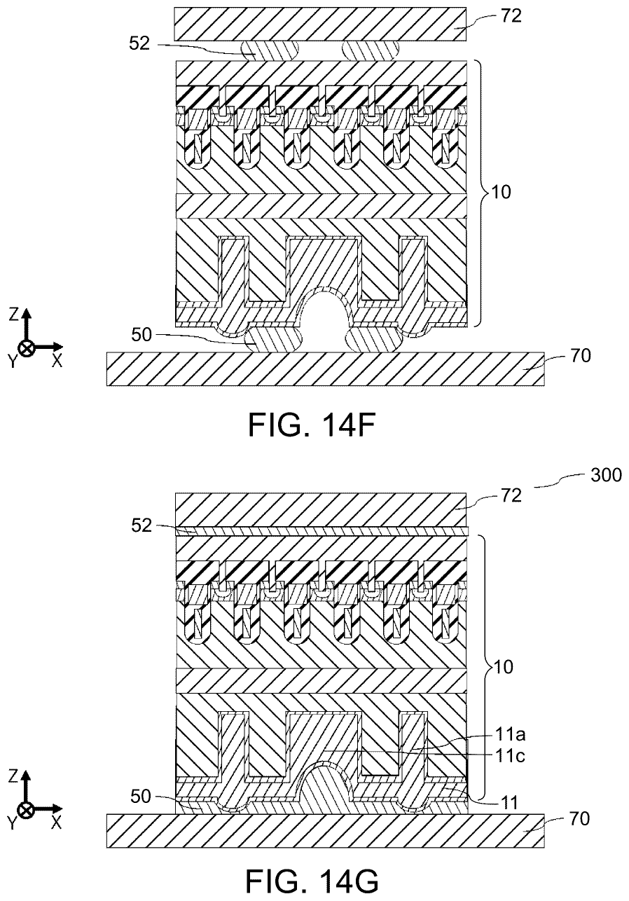

Next, an example of a method of manufacturing the semiconductor device 300 according to the third embodiment illustrated in FIG. 5 will be described with reference to FIGS. 14A to 14F. The semiconductor device 100 according to the first embodiment and the semiconductor device 200 according to the second embodiment can also be manufactured through, for example, similar steps.

The manufacturing steps illustrated in FIGS. 14A to 14F are, for example, steps after the structure on the second electrode 12 side among the structures of the chip 10 illustrated in FIG. 1 is formed. In FIGS. 14A to 14F, among the structures of the chip 10, the structure on the second electrode 12 side and the structure of the substrate 20 are not illustrated. In addition, the upper and lower sides are reversed from those in FIG. 1.

FIG. 14A illustrates a step of performing selective formation on the first main surface 20a by using a resist 80 as a mask after forming, for example, the sixth semiconductor region 26 (not illustrated) in the substrate 20. A mask pattern of the resist 80 is formed by, for example, photolithography.

FIG. 14B illustrates a step of forming a first opening Ha and a second opening Hc by removing the substrate 20 in a region where the resist 80 is not formed. The first opening Ha is smaller in volume than the second opening Hc. For example, a first width Wa of the first opening Ha in the X direction is smaller than a second width Wc of the second opening Hc.

The first opening Ha and the second opening Hc are formed through etching, for example. The etching includes isotropic etching or anisotropic etching. The first opening Ha and the second opening Hc may be formed through both isotropic etching and anisotropic etching. For example, isotropic etching, formation of a protective film, and partial removal of the protective film using anisotropic etching may be repeated.

Next, as illustrated in FIG. 14C, after the resist 80 is removed, the first metal layer ML1 is formed on the surfaces of the first main surface 20a, the first opening Ha, and the second opening Hc. The first metal layer ML1 is provided through sputtering or CVD, for example. The first metal layer ML1 contains, for example, at least one of Ti, Cu, Ta, N, TiCu, TiNCu, TiN, or TaN.

Subsequently, as illustrated in FIG. 14D, the first electrode 11 in contact with the first metal layer ML1 is formed. The first electrode 11 is provided through, for example, plating. The first electrode 11 is formed to embed the first opening Ha and the second opening Hc by, for example, an electrolytic plating method. The first metal layer ML1 may be, for example, a seed layer for plating processing. The first electrode 11 contains, for example, Cu.

The first region 11a of the first electrode 11 formed in the first opening Ha is formed to be thicker in the Z direction than the third region 11c of the first electrode 1 formed in the second opening Hc. For example, by selecting a plating processing method, the smaller the volume of the opening, the larger the thickness of the layer to be deposited in the Z direction. The plating processing is performed by, for example, an electrolytic plating method. In addition, depending on plating processing methods, an amount of deposition on the first opening Ha and the second opening Hc can be made larger than an amount of deposition on the first main surface 20a as the layer region 11L. The layer region 11L is thinner in the Z direction than the first region 11a and the third region 11c, and is formed along the first main surface 20a.

Next, as illustrated in FIG. 14E, the second metal layer ML2 is formed on the surface of the first electrode 11. The second metal layer ML2 is provided through sputtering, for example. The second metal layer ML2 contains, for example, at least one metal element of Ti, Ni, Ag, or Au.

Further, the chip 10 illustrated up to FIG. 14E is turned upside down, and as illustrated in FIG. 14F, the chip 10 is mounted on the conductor 70 such that the first electrode 11 and the conductor 70 are in contact with each other via the bonding layer 50. A conductor 72 is disposed on the second electrode 12 via a bonding layer 52. The bonding layers 50 and 52 are provided in, for example, a ball shape, and are not necessarily layered in the step in FIG. 14E. The conductor 72 is, for example, a connector containing Cu. The bonding layer 52 includes, for example, solder.

Finally, by heating the semiconductor device 300 while sandwiching the chip 10 between the conductors 70 and 72, the bonding layers 50 and 52 are melted and allowed to flow between the chip 10 and the conductors 70 and 72 as illustrated in FIG. 14G, and then the chip and the conductors 70 and 72 are bonded through cooling. The conductor 72 is, for example, a part of a metal plate connected to a source electrode of a MOSFET.

When the bonding layer 50 flows between the chip 10 and the conductor 70, the material constituting the bonding layer 50 is extruded below the first region 11a of the first electrode 11, and the material constituting the bonding layer 50 flows below the third region 11c. Therefore, in the Z direction, the bonding layer 50 becomes thin below the first region 11a, and the bonding layer 50 becomes thick below the third region 11c.

In the above description, the first electrode 11 and the first metal layer ML1 and the second metal layer ML2 are described as separate elements, but for example, the first electrode 11 may have a plurality of layers. That is, it may be considered that the first metal layer ML1 and the second metal layer ML2 are also included in the first electrode 11. For example, the layer region 11L of the first electrode 11 may include at least the first metal layer ML1 or the second metal layer ML2.

The embodiments have been described above with reference to specific examples. However, embodiments are not limited to these specific examples. That is, those obtained by appropriately changing the design of these specific examples by those skilled in the art are also included in the scope of the embodiments as long as they have the features of the embodiments. The element included in each specific example described above and the disposition, the material, the condition, the shape, the size, and the like thereof are not limited to those exemplified, and can be changed as appropriate.

In addition, the element included in each of the above-described embodiments can be combined as far as technically possible, and combinations thereof are also included in the scope of the embodiments as long as they include the features of the embodiments. In addition, within the scope of the idea of the embodiments, a person skilled in the art can conceive of various modification examples and correction examples, and it is understood that the modification examples and correction examples are also included in the scope of the embodiments.

Although some embodiments of the present invention have been described, these embodiments have been presented as examples, and are not intended to limit the scope of the invention. These novel embodiments can be implemented in various other forms, and various omissions, substitutions, and changes can be made without departing from the concept of the invention. These embodiments and modifications thereof are included in the scope and concept of the invention, and are included in the invention described in the claims and the equivalent scope thereof.

What is claimed is:

1. A semiconductor device comprising:
a substrate having a first main surface and a second main surface on a side opposite to the first main surface;
a first electrode provided on the first main surface;
a second electrode provided on the second main surface; and
a MOSFET provided on the second main surface side of the substrate and having the first electrode as a drain electrode and the second electrode as a source electrode, wherein
the first electrode has
a layer region provided on the first main surface, and
a first region extending from the first main surface into the substrate in a first direction from the first electrode toward the second electrode, the first region being adjacent to the layer region, and
a lower surface of the first electrode protrudes in a direction opposite to the first direction in the first region.

2. The semiconductor device according to claim 1, wherein
the first electrode further includes a second region that extends into the substrate from the first main surface in the first direction, and is adjacent to the layer region, the substrate is interposed between the first region and the second region in a second direction intersecting the first direction.

3. The semiconductor device according to claim 2, wherein
a length of the first region in the second direction is smaller than a length of the second region in the second direction.

4. The semiconductor device according to claim 3, wherein
the lower surface of the first electrode has a flat surface parallel to the second direction in the second region.

5. The semiconductor device according to claim 1, further comprising:
a first metal layer provided between the substrate and the first electrode and containing at least one of Ti, Cu, Ta, N, TiCu, TiNCu, TiN, or TaN.

6. The semiconductor device according to claim 1, wherein
the substrate includes
a first semiconductor region of a first conductivity type provided on the first electrode,
a second semiconductor region of the first conductivity type provided on the first semiconductor region,
a third semiconductor region of a second conductivity type provided on the second semiconductor region,
a fourth semiconductor region of the first conductivity type provided on the third semiconductor region and connected to the second electrode, and
a buffer region of the first conductivity type provided between the first semiconductor region and the second semiconductor region and having a higher impurity concentration of the first conductivity type than an impurity concentration of the second semiconductor region, and
a distance between the first region and the second electrode in the first direction is longer than a distance between the first semiconductor region and the second electrode in the first direction.

7. The semiconductor device according to claim 1, further comprising
a third electrode provided on the second main surface of the substrate and separated from the second electrode, wherein
the second main surface has an inter-electrode region located between the second electrode and the third electrode, and
the first region is provided at a position overlapping the inter-electrode region in the first direction.

8. The semiconductor device according to claim 2, wherein
a plurality of gate electrodes of the MOSFET provided on the second main surface of the substrate aligns in the second direction and extends in a third direction orthogonal to the first direction and the second direction; and
a plurality of the first regions aligns in the second direction and extends in the third direction.

9. The semiconductor device according to claim 1, further comprising:
a conductor; and
a bonding layer, wherein
the first electrode is provided on the conductor via the bonding layer, and is electrically connected to the conductor via the bonding layer.

10. The semiconductor device according to claim 9, wherein
the conductor contains Cu, and
the bonding layer includes solder.

11. The semiconductor device according to claim 10, further comprising
a second metal layer provided on the lower surface of the first electrode and containing at least one of Ti, Ni, Ag, or Au.

12. A semiconductor device comprising:
a substrate having a first main surface and a second main surface on a side opposite to the first main surface;
a first electrode provided on the first main surface;
a second electrode provided on the second main surface; and
a MOSFET provided on the second main surface side of the substrate and having the first electrode as a drain electrode and the second electrode as a source electrode, wherein
the first electrode has
a layer region provided on the first main surface along the first main surface, and
a third region extending from the first main surface into the substrate in a first direction from the first electrode toward the second electrode, the third region being adjacent to the layer region, and
a lower surface of the first electrode is recessed in the third region in the first direction.

13. The semiconductor device according to claim 12, further comprising
a first metal layer provided between the substrate and the first electrode and containing at least one of Ti, Cu, Ta, N, TiCu, TiNCu, TiN, or TaN.

14. The semiconductor device according to claim 12, further comprising:
a conductor; and
a bonding layer, wherein
the first electrode is provided on the conductor via the bonding layer, and is electrically connected to the conductor via the bonding layer.

15. The semiconductor device according to claim 14, wherein
the conductor contains Cu, and
the bonding layer includes solder.

16. The semiconductor device according to claim 15, further comprising
a second metal layer provided on the lower surface of the first electrode and containing at least one of Ti, Ni, Ag, or Au.

17. A method of manufacturing the semiconductor device according to claim 1,
the first electrode further includes a second region that extends into the substrate from the first main surface in the first direction, and is adjacent to the layer region, the substrate is interposed between the first region and the second region in a second direction intersecting the first direction,
the method comprising:
forming each of the first region and the second region of the first electrode by embedding a first opening having a first width in the second direction and a second opening having a second width larger than the first width in the second direction by an electrolytic plating method, wherein the lower surface of the first electrode protrudes in the first region in a direction opposite to the first direction by selecting a predetermined width as the first width.

18. A method of manufacturing the semiconductor device according to claim 12 comprising:
forming the third region of the first electrode by embedding a third opening having a third width in the second direction by an electrolytic plating method, wherein the lower surface of the first electrode is recessed in the third region in the first direction by selecting the third width.
